(19) United States
(12) Patent Application Publication
(10) Pub. No.: US 2012/0329359 A1
(43) Pub. Date: Dec. 27, 2012

(54) POWERED TOY BUILDING STRUCTURES AND RELATED DEVICES AND METHODS

(76) Inventor: Jonathan Capriola, Sarasota, FL (US)

(21) Appl. No.: 13/530,088

(22) Filed: Jun. 21, 2012

Related U.S. Application Data
(60) Provisional application No. 61/499,435, filed on Jun. 21, 2011.

(51) Int. Cl. A63H 33/04; H05K 3/32

(52) U.S. Cl. 446/91; 29/832

(57) ABSTRACT

A powered toy budding block includes a printed circuit board, at least a first electrical component mounted to the printed circuit board, at least a first electrical connector mounted to an edge of the printed circuit board and electrically connected to the first electrical component, and a body defining a hollow interior cavity, and at least a first mechanical connector, the printed circuit board and the first electrical component being arranged in the hollow interior cavity with the first electrical connector extending into the first mechanical connector. The first electrical component can be a light emitting diode arranged over an opening in the printed circuit board. The first electrical component can also be a digital audio player, operable to play a digital audio file through a speaker arranged in the body.

### CROSS-REFERENCE TO RELATED APPLICATION

This application claims the benefit of U.S. Provisional Application Ser. No. 61/499,435, filed on Jun. 21, 2011, the contents of which are herein incorporated by reference in their entirety.

### FIELD OF THE INVENTION

The present invention relates to powered toy building structures, and more particularly, to toy building structures that, when assembled, transmit power for various functions via connections between the structures.

### BACKGROUND OF THE INVENTION

The present inventor has previously invented illuminated toy building structures, in which a plurality of blocks or other building elements are assembled by connections that double as electrical connections. In this manner, a plurality of illuminated blocks can be powered from a single power source, giving relatively free reign to the imagination of users to assemble to large numbers of blocks into a wide range of models. Examples of such blocks can be seen in the present inventor's U.S. Pat. No. 7,731,558 and U.S. patent application Ser. No. 12/547,183, the contents of which are herein incorporated by reference in their entirety.

Despite the popularity of these illuminated building structures, further improvements are possible, both with respect to the illuminated building structures themselves, and in devices for use therewith.

### SUMMARY OF THE INVENTION

In view of the foregoing, it is an object of the present invention to provide improved powered toy building structures and related devices and methods. According to an embodiment of the present invention an illuminated toy building block comprises a printed circuit board having opposed first and second circuit board surfaces and defining at least one circuit board opening extending therethrough, the circuit board opening having an opening perimeter, a majority of the opening perimeter being surrounded by the printed circuit board, a light emitting diode mounted to the first circuit board surface and extending over the circuit board opening such that the light emitting diode is visible from the first and the second circuit board surfaces, at least a first electrical connector mounted to a first edge of the printed circuit board and electrically connected to the light emitting diode, and a generally transparent body defining a hollow interior cavity and at least a first mechanical connector, the printed circuit board and the light emitting diode being arranged in the hollow interior cavity with the first electrical connector extending into the first mechanical connector.

According to another embodiment of the present invention, a powered toy building block comprises a printed circuit board, a digital audio player mounted to the printed circuit board, the digital music audio including a memory storage device adapted to store at least one digital audio file stored therein, a speaker in signal communication with the digital audio player, at least a first electrical connector mounted to an edge of the printed circuit board and electrically connected to the digital audio player and the speaker, and a body defining a hollow interior cavity and at least a first mechanical connector, the printed circuit board, the digital audio player and the speaker being arranged in the hollow interior cavity with the first electrical connector extending into the first mechanical connector, the body being configured such that sound from the speaker is audible therethrough. The powered toy building block is electrically and mechanically connectable via the first electrical and mechanical connectors to at least one other powered toy building block to receive electrical power therefrom and play the at least one audio file.

According to a further embodiment of the present invention, a powered toy building block comprises a printed circuit board having at least one circuit board alignment element, at least a first electrical component mounted to the printed circuit board, at least a first electrical connector mounted to an edge of the printed circuit board and electrically connected to the first electrical component, and a body defining a hollow interior cavity, at least one body alignment element complementary with the circuit board alignment element in the hollow interior cavity, and at least a first mechanical connector, the printed circuit board and the first electrical component being arranged in the hollow interior cavity with the first electrical connector extending into the first mechanical connector. Proper placement of the printed circuit board within the hollow interior cavity is ensured by complementary engagement of the circuit board and body alignment elements.

A powered toy budding block kit can include a plurality of the powered toy building blocks with digital audio players, each digital audio player including a different pre-loaded digital audio file.

According to a method aspect, a method of making a powered toy building block comprises mounting a first electrical component to a printed circuit board, mounting a first electrical connector to an edge of the printed circuit board such that the first electrical connector and the first electrical component are electrically connected, arranging the printed circuit board in a first body portion, and connecting a second body portion to the first body portion to form a body having at least a first mechanical connector with a hollow interior cavity defined between the first and second body portions, the printed circuit board therein and the first electrical connector extending into the first mechanical connector.

According to another method aspect, the printed circuit board defines a circuit board opening at least partially surrounded by the printed circuit board and the first electrical component is a light emitting diode mounted over the circuit board opening so as to be visible from both sides of the printed circuit board.

According to a further method aspect, the printed circuit board has at least one circuit board alignment element and the first body portion has at least one body alignment element complementary with the circuit board alignment element, proper connection of the first and second body portions being mechanically inhibited unless the circuit board and body alignments elements in complementary engagement.

These and other objects, aspects and advantages of the present invention will be better appreciated in view of the drawings and following detailed description of preferred embodiments.

### BRIEF DESCRIPTION OF THE DRAWINGS

FIG. 1 is a perspective view of an assembly of powered toy building structures, according to an embodiment of the present invention;

FIG. 2 is a perspective view of an exemplary one of the powered toy building structures of FIG. 1, with a top portion removed to show interior details;

FIG. 3 is a circuit diagram of electrical components of the exemplary powered toy building structure of FIG. 1;

FIG. 4 is a perspective view of a powered toy building structure, according to an alternate embodiment of the present invention;

FIG. 5 is an exploded view of the powered toy building structure of FIG. 4; and

FIG. 6 is a perspective view of a powered toy building structure, according to a further embodiment of the present invention.

### DETAILED DESCRIPTION OF PREFERRED EMBODIMENTS

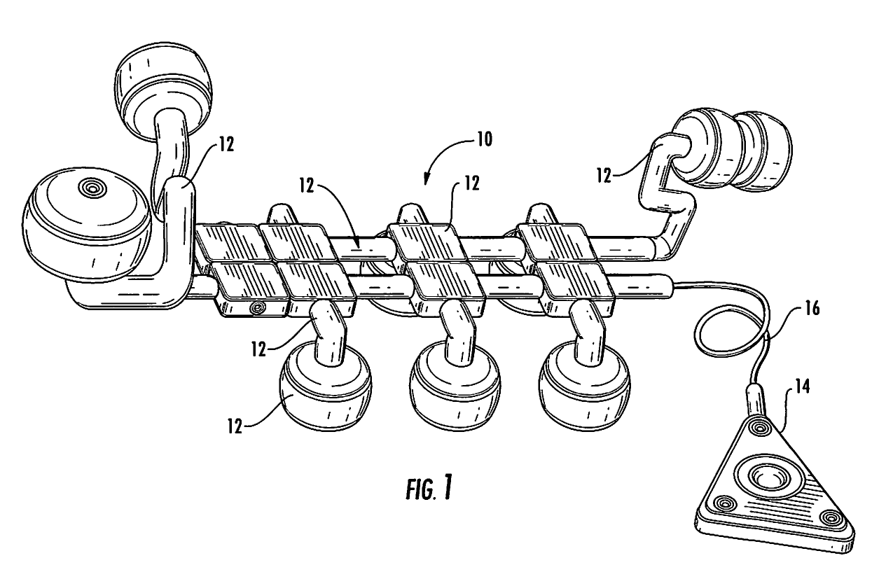

According to an embodiment of the present invention, referring to FIG. 1, a powered toy building structure assembly 10 includes a plurality of releasably interconnected toy building blocks 12 powered by a power supply 14. A power cable 16 can be used to releasably connect the blocks 12 to the power supply 14, or the blocks 12 can releasably connect directly to the power supply 14. Once single block 12 is connected to the power supply 14 and the power supply 14 is energized, every other block 12 connected directly or indirectly thereto will receive electrical power from the power supply 14 to power electrical components therein; for instance, for illumination, the playing of sounds, or other functions.

The present invention is not necessarily limited to the shaped of blocks 12 shown in FIG. 1, and combinations of blocks 12 can be assembled into virtually any design imaginable. Additionally, other power supplies 14 can be employed in connection with the blocks 12; for example, as disclosed in the previously referenced patent and patent application of the present invention. Such power supplies 14 can supply either a steady, continuous power, or supply power in one or more predetermined patterns.

Referring to FIG. 2, an exemplary one of the blocks 12 is shown. It will be appreciated that the following description of features of the exemplary block 12 could be readily applied to any of the blocks 12 shown, as well as to blocks 12 of other shapes and configurations.

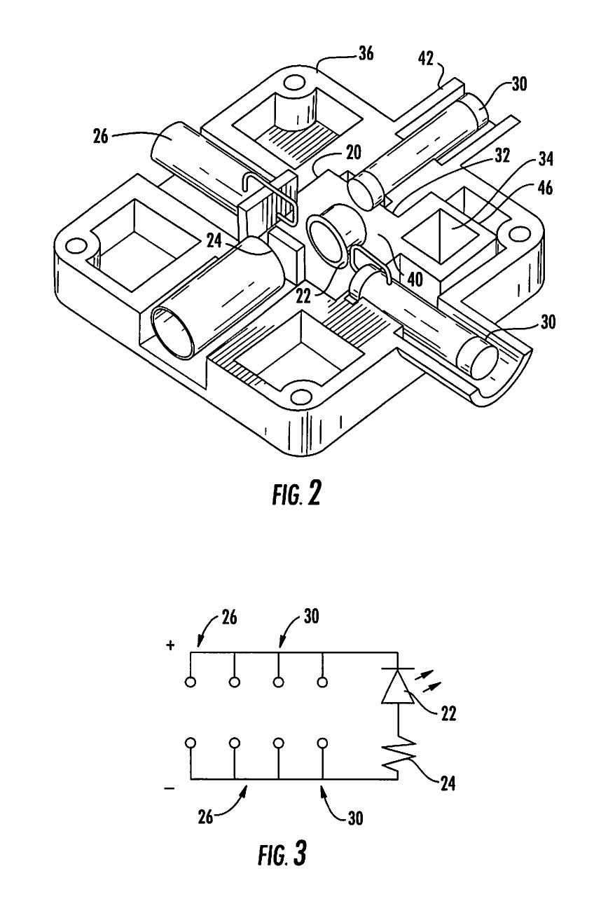

The block 12 includes a printed circuit board 20 to which one or more electrical components 22, 24 are mounted, such as a lighting emitting diode (LED) 22 and resistor 24. A plurality of electrical connectors 26, 30 are mounted to edges of the circuit board 20 and electrically connected to the electrical components 22, 24. The electrical connectors 26, 30 are preferably male and/or female coaxial electrical connectors, such that an electrical circuit including the electrical components 22, 24 can be completed by connecting any single connector 26, 30, as illustrated in the circuit diagram of FIG. 3.

Advantageously for use with the LED 22, a circuit board opening 32 is defined extending between opposite surfaces of the printed circuit board 20. In the depicted block 12, the opening 32 is completely surrounded by the circuit board 20. Preferably, at least a majority of the opening 32 is surrounded by the circuit board 20; for example, the opening 32 could be bounded on three sides by the circuit board 20. The LED 22 is mounted over the opening 32, allowing the LED 22, and light emitted therefrom, to be seen from both sides of the circuit board 20. The LED 22 can be mounted so as to extend into the opening 32, thus decreasing the effective space required within the block 12 by the LED 22.

It will be appreciated that, by assembling the electrical components 22, 24 and connectors 26, 30 onto the printed circuit board 20, the assembly time for the building structures 12 can be decreased and the accurate placement of electrical components can be simultaneously facilitated. The circuit board 20 also includes a circuit board alignment element 34. The circuit board alignment element 34 can help ensure proper placement of the circuit board 20 within the block 12, as will be explained in greater detail below.

The block 12 also includes a body 36, which is advantageously generally transparent so that the interior components can be seen therethrough, although non transparent bodies 36, or bodies 36 with only limited areas of transparency or translucency can be used within the scope of the present invention. The body 36 is preferably formed of two portions, a top portion of which is removed in FIG. 2 to better show internal details of the block 12. The body 36 defines a hollow interior cavity 40 between the portions when connected, in which the printed circuit board 20 is arranged.

The body 36 includes mechanical connectors 42, 44, such as male connectors 42 and female connectors 44, extending outwardly from the interior cavity 40. With the printed circuit board 20 properly placed in the interior cavity 40, the electrical connectors 26, 30 extend into respective mechanical connectors 44, 42. Thus, a single mechanical connection between adjacent blocks 12 suffices to make a complete electrical connection therebetween.

To help ensure proper placement of the circuit board 20, a body alignment element 46 is formed in the interior cavity 40 that is complementary with the circuit board alignment element 34. With the circuit board and body alignment elements 34, 46 in complementary engagement, the circuit board 20 will be properly placed within the body 12. Advantageously, the circuit board 20 will physically not fit in the interior cavity 40 unless complementary engagement is achieved, mechanically inhibiting connection of the body 36 portions until the correct placement is achieved.

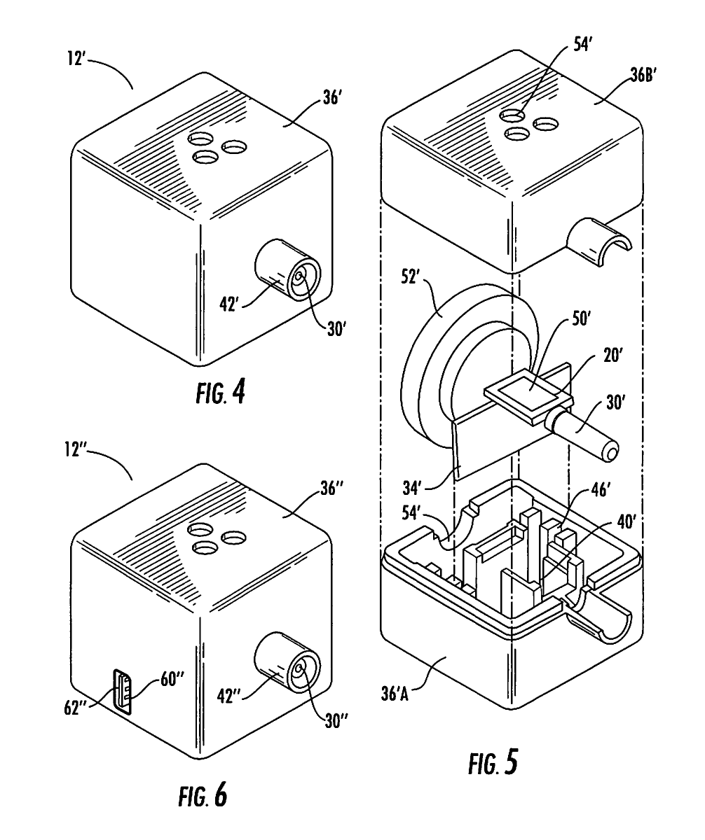

Referring to FIGS. 4 and 5, an alternate block embodiment will be described. In referring to alternate embodiments, like reference numerals are used to refer to like elements, annotated with one or more prime 0 notations. The block 12′ of FIGS. 4 and 5 is an audio-capable block, and includes printed circuit board 20′ with a digital audio player 50′ mounted thereon, and at least one electrical connector 30′ mounted to an edge thereof and electrically connected to the digital audio player 50′.

The digital audio player 50′ includes a memory device on which one more digital audio files can be stored for playing via a speaker 52′ . Advantageously, a plurality of openings 54 can be defined through the body 36′ to better allow the speaker 52′ to be audible therethrough.

The digital audio player 50′ can be pre-loaded with one or more audio files, and automatically play such file(s) when power is applied to the block 12′. Alternately, another actuation method could be applied to trigger the playing of digital audio files, such as sound or motion activation, or an electrical switch. A plurality of different blocks 12′ could be packaged together into a kit, with each block 12′ featuring a different pre-loaded digital audio file.

Referring to FIG. 6, a block 12″ can further be equipped with a data connector 60″ accessible via a data connector port 62″ in the body 36″, such a micro universal serial bus (micro-USB) connector. A user can upload audio data files to the memory device of the digital audio player via the data connector 60″. The present invention is not necessarily limited to any particular type of digital audio player, to any type of digital audio file, to any type of data connector, or to any particular audio date file transfer regime. In addition to their audio capabilities, the blocks 12′, 12″ can also be illuminated.

The audio blocks 12′ and 12″ can readily be connected to the power supply 14 (with or without cable 16) and to other blocks 12, such as illuminated blocks 12, to further increase the excitement and design possibilities for powered toy building structure assemblies.

In general, the foregoing description is provided for exemplary and illustrative purposes; the present invention is not necessarily limited thereto. Rather, those skilled in the art will appreciate that additional modifications, as well as adaptations for particular circumstances, will within the scope of the invention as herein shown and described and of the claims appended hereto.

What is claimed is:

1. An illuminated toy building block comprising:
a printed circuit board having opposed first and second circuit board surfaces and defining at least one circuit board opening extending therethrough, the circuit board opening having an opening perimeter, a majority of the opening perimeter being surrounded by the printed circuit board;
a light emitting diode mounted to the first circuit board surface and extending over the circuit board opening such that the light emitting diode is visible from the first and the second circuit board surfaces;
at least a first electrical connector mounted to a first edge of the printed circuit board and electrically connected to the light emitting diode; and
a generally transparent body defining a hollow interior cavity and at least a first mechanical connector, the printed circuit board and the light emitting diode being arranged in the hollow interior cavity with the first electrical connector extending into the first mechanical connector.

2. The illuminated toy building block of claim 1, wherein the opening perimeter is completely surrounded by the printed circuit board.

3. The illuminated toy building block of claim 1, further comprising a second electrical connector mounted to a second edge of the printed circuit board and electrically connected to the light emitting diode, such that the light emitting diode can be powered by electrical power supplied to either the first or the second electrical connector;
wherein the generally transparent body includes a second mechanical connector, the second electrical connector extending thereinto.

4. The illuminated toy building block of claim 1, wherein the light emitting diode extends into the circuit board opening.

5. The illuminated toy building block of claim 1, wherein the printed circuit board has at least one circuit board alignment element and the generally transparent body has at least one body alignment element complementary with the circuit board alignment element in the hollow interior cavity, proper placement of the printed circuit board within the hollow interior cavity being ensured by engagement of the circuit board and body alignment elements.

6. The illuminated toy building block of claim 1, further comprising a resistor mounted to the printed circuit board and electrically connected to the light emitting diode.

7. A powered toy building block comprising:
a printed circuit board having at least one circuit board alignment element;
at least a first electrical component mounted to the printed circuit board;
at least a first electrical connector mounted to an edge of the printed circuit board and electrically connected to the first electrical component; and
a body defining a hollow interior cavity, at least one body alignment element complementary with the circuit board alignment element in the hollow interior cavity, and at least a first mechanical connector, the printed circuit board and the first electrical component being arranged in the hollow interior cavity with the first electrical connector extending into the first mechanical connector;
wherein proper placement of the printed circuit board within the hollow interior cavity is ensured by complementary engagement of the circuit board and body alignment elements.

8. The powered toy building block of claim 7, wherein the first electrical component is a light emitting diode.

9. The powered toy building block of claim 7, wherein the first electrical component is a digital audio player.

10. The powered toy building block of claim 7, wherein the at least one circuit board alignment element is a protrusion and the at least one body alignment element is a complementary recess.

11. The powered toy building block of claim 7, wherein the body includes connected first and second body portions, the hollow interior cavity being defined therebetween, the body alignment element being located in only one of the first and second body portions such that the first and second body portions can only be connected with the circuit board and body alignment elements complementarily engaged.

12. A method of making a powered toy building block, the method comprising:
mounting a first electrical component to a printed circuit board;
mounting a first electrical connector to an edge of the printed circuit board such that the first electrical connector and the first electrical component are electrically connected;
arranging the printed circuit board in a first body portion; and
connecting a second body portion to the first body portion to form a body having at least a first mechanical connector with a hollow interior cavity defined between the first and second body portions, the printed circuit board therein and the first electrical connector extending into the first mechanical connector.

13. The method of claim 12, wherein the printed circuit board defines a circuit board opening at least partially surrounded by the printed circuit board and the first electrical component is a light emitting diode mounted over the circuit board opening so as to be visible from both sides of the printed circuit board.

14. The method of claim 12, wherein the printed circuit board has at least one circuit board alignment element and the first body portion has at least one body alignment element complementary with the circuit board alignment element, proper connection of the first and second body portions being mechanically inhibited unless the circuit board and body alignments elements in complementary engagement.

15. A powered toy building block comprising:
a printed circuit board;
a digital audio player mounted to the printed circuit board, the digital music audio including a memory storage device adapted to store at least one digital audio file stored therein;
a speaker in signal communication with the digital audio player;
at least a first electrical connector mounted to an edge of the printed circuit board and electrically connected to the digital audio player and the speaker; and
a body defining a hollow interior cavity and at least a first mechanical connector, the printed circuit board, the digital audio player and the speaker being arranged in the hollow interior cavity with the first electrical connector extending into the first mechanical connector, the body being configured such that sound from the speaker is audible therethrough;
wherein the powered toy building block is electrically and mechanically connectable via the first electrical and mechanical connectors to at least one other powered toy building block to receive electrical power therefrom and play the at least one audio file.

16. The powered toy building block of claim 15, wherein the at least one digital audio file is stored in the memory storage device.

17. The powered toy building block of claim 15, further comprising a data connector arranged in the body in signal communication with the digital audio player, a data connector port being defined in the body and allowing external access to the data connector port, the at least one digital audio file being transferrable to the digital audio player via the data connector.

18. The powered toy building block of claim 17, wherein the digital audio player automatically plays the digital audio file when power is supplied to the first electrical connector.

19. A powered toy building block kit comprising a plurality of the powered toy building blocks of claim 15 packaged as a set.

20. The powered toy building block kit of claim 19, wherein the digital audio player of each of the plurality of powered toy building blocks includes a different pre-loaded digital audio file.
